(19) United States
(12) Patent Application Publication
(10) Pub. No.: US 2008/0119022 A1
(43) Pub. Date: May 22, 2008

(54) METHOD OF MAKING EEPROM TRANSISTORS

(75) Inventor: Bohumil Lojek, Colorado Springs, CO (US)

Correspondence Address: SCHNECK & SCHNECK, P.O. BOX 2-E, SAN JOSE, CA, 95109-0005, US

(73) Assignee: ATMEL CORPORATION, San Jose, CA (US)

(21) Appl. No.: 11/562,776

(22) Filed: Nov. 22, 2006

(51) Int. Cl. H01L 21/336

(52) U.S. Cl. 438/266; 257/E21.422

(57) ABSTRACT

A first mask set is used to define parallel active area stripes while a second mask set with memory cell stripes is perpendicular to the first mask set. The second mask set features cell masks with spaced apart branches, one for a non-volatile memory cell. The branch for the non-volatile memory cell has a mask portion for defining a subsurface charge region for communicating charge to a floating gate. The branches can use sub-masks for defining openings that are less than feature size, for example, for defining the subsurface charge region, yet allowing regions apart from spacers to define feature size and larger gates for desired channel lengths. The implantation of the charge region allows for self-aligned implanting of source-drain regions at locations that have been optimized for desired channel lengths or other parameters. By implanting source-drain regions late in the manufacturing process, there is no overlap with previously formed gates.

### TECHNICAL FIELD

The invention relates to EEPROM transistor manufacturing, and, in particular to manufacturing such transistor with self-aligned source and drain electrodes.

### BACKGROUND ART

Most EEPROM transistors have a floating gate over a substrate surface that transfers electrons or holes into or from a subsurface drain or drain extension that is separated by thin oxide by a small tunnel window. The subsurface drain is usually formed by one or more implant regions. Because of a need to have a drain implant region connected with the implant region under the tunnel window, preferably directly beneath it, drain extensions are usually implanted before a floating gate is built and hence not aligned with edges of the floating gate. An advantage of alignment, or preferably self-alignment is that devices can be manufactured with good reproducibility and dimensions of the channel can be made more favorable, particularly in devices having feature size dimensions. A drain extension that is partially under the floating gate has greater cell capacitance relative to the floating gate which leads to slower programming. A drain or drain extensions that is partially under the floating gate must be monitored for the short channel effect, a deleterious condition that leads to poor transistor performance.

On the one hand it is desirable to have source and drain separated at distances which avoid the short channel effect. On the other hand, a subsurface implant is needed beneath or very close to the tunnel window. A third consideration is that it is desirable that the largest structures of the transistor be feature size, F, or a few multiples of feature size, where feature size is the smallest dimension that can be made by lithography. As a specific dimension, F depends on lithographic equipment, but is scalable to whatever lithographic equipment is available. In modern stepper equipment, F is typically in the range of 40 to 150 nanometers and is forecast to become smaller. F depends on the wavelength of the exposing light multiplied by a resolution factor and divided by the numerical aperture of the lithographic system. The resolution factor depends on several variables in the photolithographic process including the quality of the photoresist used and the resolution enhancement techniques such as phase shift masks, off-axis illumination and optical proximity correction. In the industry, F is a characteristic of particular semiconductor manufacturing equipment that uses photolithography. For example if source, floating gate and drain were all feature size, F, and did not overlap, then the transistor would have a dimension of 3 F in one direction. If an accompanying select transistor had a feature size gate and a feature size source-drain, sharing an electrode with the floating gate transistor, for a dimension of 2 F, then the overall dimension in the one direction would be 5 F, a very small memory cell. In actuality some dimensions are preferably based on feature size, but are made a bit larger to optimize channel lengths, or the like. See U.S. Pat. No. 6,624,027 to E. Daemen et al., assigned to the assignee of the present invention entitled, “Ultra Small Thin Windows in Floating Gate Transistors Defined by Lost Nitride Spacers”.

### SUMMARY OF THE INVENTION

The present invention is a manufacturing method for an EEPROM and for EEPROMs that can be used in NOR arrays, i.e. having a select transistor as part of the memory cell. In the method of the invention a floating gate implant region is first established in a smaller than F subsurface region established by a sidewall spacer implantation technique. The technique uses dual spacers as a mask to define an aperture that is smaller than F. After the implant region is established, the floating gate is established with two floating gate members that are spaced apart but electrically joined. The gate member spacing can also be established with a similar dimension, F. Source-drain implantation follows using the gates with spacers as masks, producing three self-aligned source-drain regions at desired distances yet an implanted region exists directly below the tunnel window from the prior implantation step. Three of the four regions are joined by annealing to form a drain electrode, while the fourth region is a spaced apart source electrode.

A single two branch floating gate mask is used to establish a plurality of sidewalls for the three source-drain implant regions mentioned above. Note that all portions of the drain are self-aligned, leading to reliable transistor manufacturing. Memory transistors are built in rows where cell sites are defined by active region stripes on a wafer or similar substrate. The single floating gate mask can be made in mirrored pairs spanning parallel active region stripes. If the floating gate masks are made having a U-shape or an H-shape, the correct orientation and spacing of adjacent gates within a cell is assured for reliable transistor manufacturing. A line of gate masks can run perpendicular to active region stripes as the basis for a tightly packed memory array, i.e. rows and columns of EEPROM memory transistors.

### BRIEF DESCRIPTION OF THE DRAWINGS

FIGS. 1-11 are side constructional views for making a transistor memory cell of the present invention.

FIG. 12 is a top view of masks used to make structures as illustrated in FIG. 11.

FIG. 13 is a top view of alternate masks used to make structures as illustrated in FIG. 11.

FIGS. 14-17 are side constructional views for making a transistor memory cell following FIG. 11.

FIG. 18 is an electrical schematic of the memory cell of FIG. 17.

### DESCRIPTION OF PREFERRED EMBODIMENT

With reference to FIG. 1, substrate 11 is typically a doped semiconductor p-type wafer suitable for manufacture of MOS devices. The silicon substrate 11 is seen to be coated with a thin layer of gate oxide 15 approximately 50-100 Angstroms thick. A first layer of polysilicon 17 is deposited over the gate oxide layer 15 by vapor deposition to a thickness of less than 1500 Angstroms, although this dimension is not critical. Over the polysilicon layer 17, another layer of oxide 19 is deposited having a thickness of approximately 60-100 Angstroms.

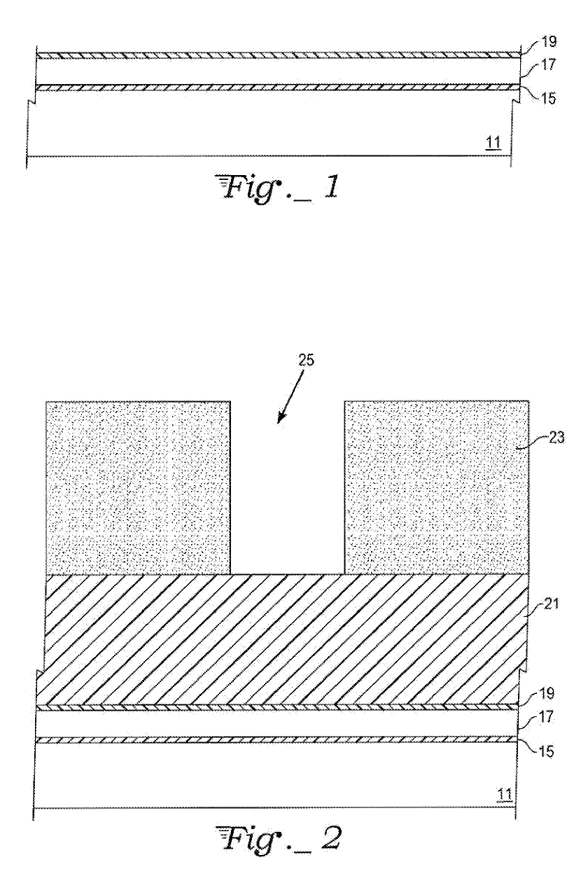

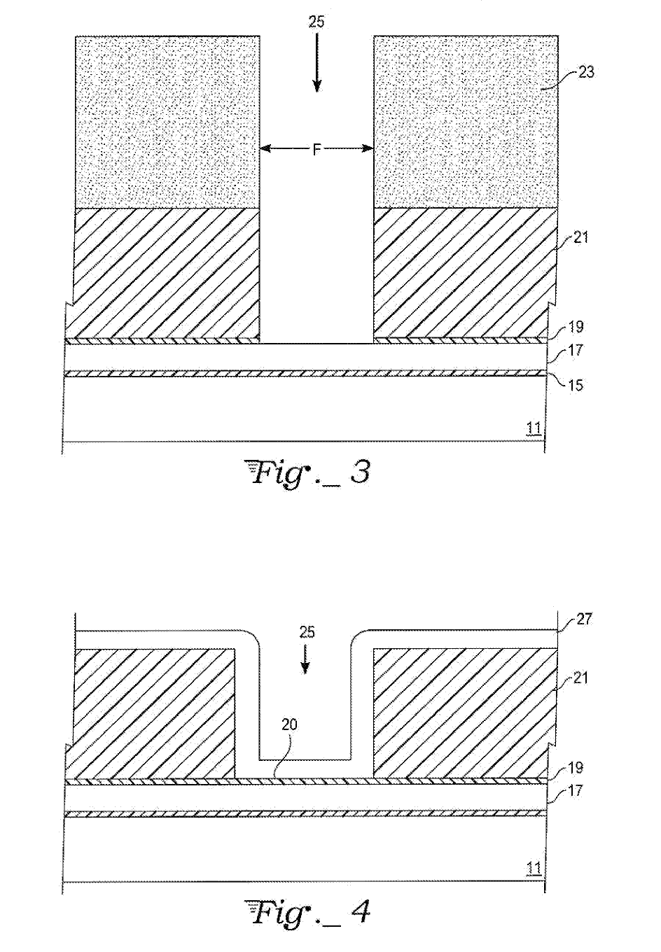

With reference to FIG. 2, over the second layer of oxide 19 is an insulative oxide layer, preferably a TEOS layer 21, is deposited having a thickness which is several times the thickness of polysilicon layer 17. It should be noted that the layers 15, 17, 19, and 21 are all planar layers extending entirely across the wafer substrate. Over the TEOS layer 21 a resist layer 23 is deposited with an opening 25 defined by a photomask. The opening 25 is ideally the smallest opening that can be defined by a mask, known as the feature size, F. The TEOS layer 21 is etches, as shown in FIG. 3. Etching is stopped at upper surface of polysilicon layer 17, meaning that oxide layer is also removed in the opening 25.

After development of the photoresist, as shown in FIG. 4, a nitride or polysilicon layer 27 extending down over the TEOS layer 21 with the layer 27 extending down into the opening 25. Prior to deposition of the layer 27 the polysilicon layer 17 is reoxidized in region 20 so that oxide will separate the nitride or poly layer 27 from polysilicon layer 17 in the region where reoxidation occurs.

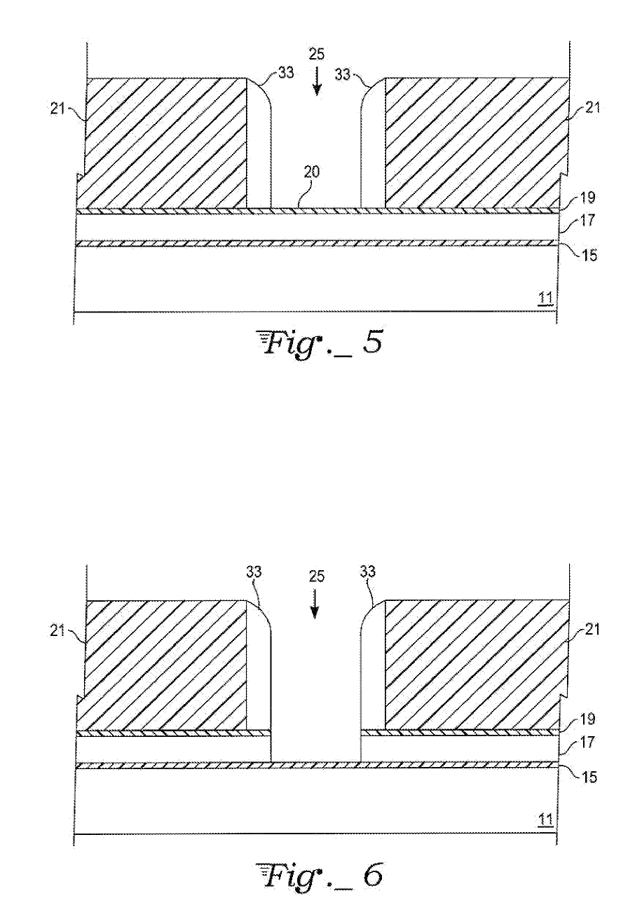

Next, the polysilicon or nitride layer 27 is mostly etched away, except for spacers 33, seen in FIG. 5, which abut the TEOS layer 21 in opening 25. The interior of this rectangle is less than the feature size F. The gap between the spacers is 10 to 50 nm. Further etching between spacers 33 takes the opening 25 to the level of gate oxide layer 15, removing re-oxidized region 20 and the polysilicon below this region, as shown in FIG. 6.

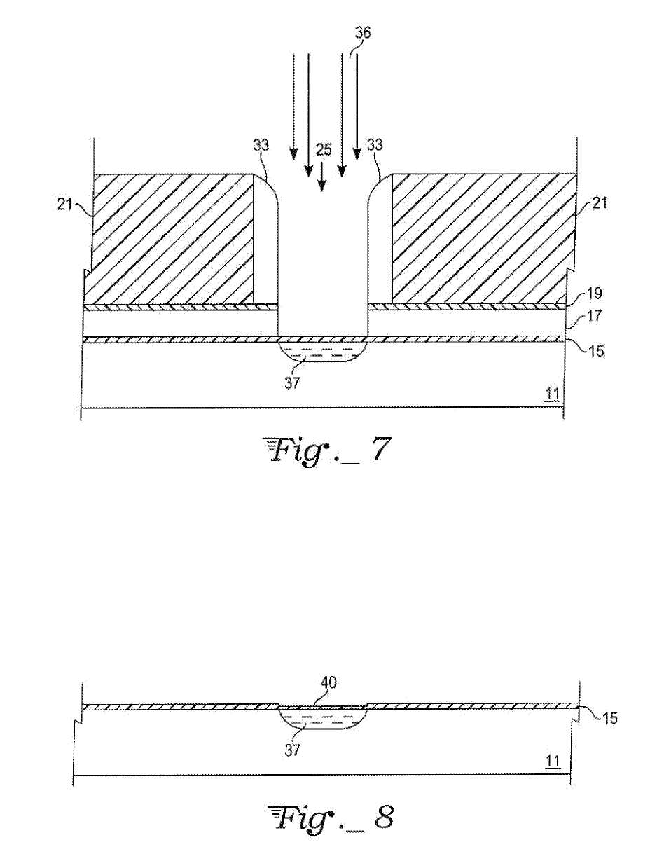

With reference to FIG. 7, an ion beam 36 is directed through opening 25 to a shallow depth in substrate 11 to create a P+ region in substrate 11. The spacers 33 and TEOS layer 21 block the beam from other areas of the substrate and poly layer 17 except where the charge implanted region 37 is indicated.

With reference to FIG. 8, the remainder of the TEOS layer 21, the spacers 33, oxide layer 19 and poly layer 17 are all removed by etching, leaving only oxide layer 15. The oxide layer 15 is also etched but then reoxidized. Photolithography is used to form a very thin oxide window 40, over the implanted region 37 as a tunnel window, with a slight step in the oxide thickness making the window thinner than surrounding oxide regions. Such a window oxide layer has a typical thickness of less than 65 Angstroms.

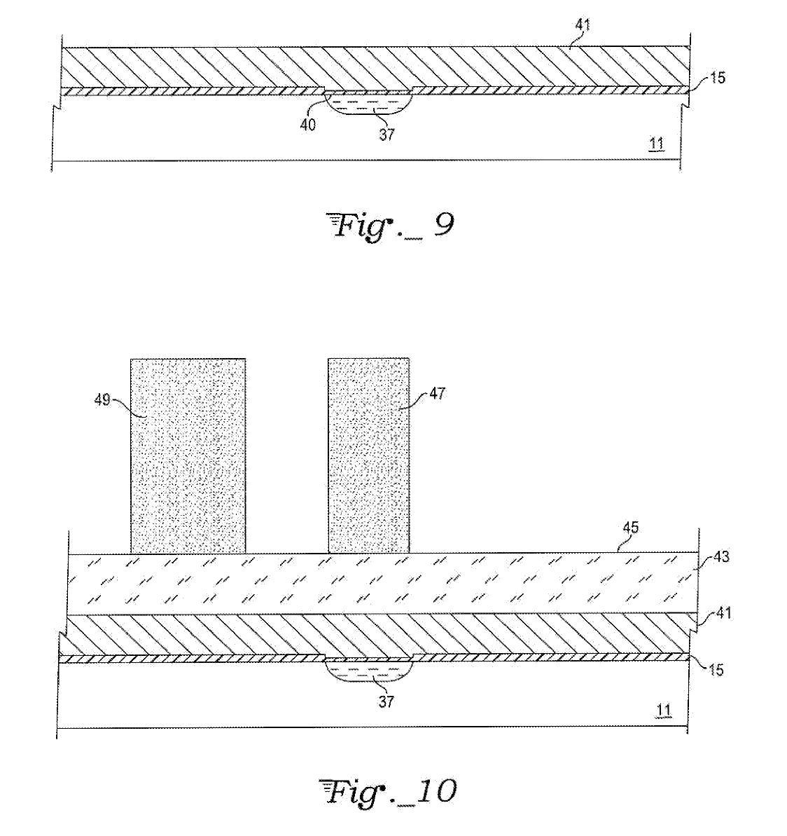

With reference to FIG. 9, a poly layer 41, approximately 500-1000 Angstroms in thickness is deposited over oxide layer 15. This layer will serve to form a floating gate. Although the poly layer 41 slumps into the window region, the poly is almost planar at its upper surface.

With reference to FIG. 10, an insulative TEOS layer 43 is deposited over poly layer 41. The thickness of TEOS layer 43 is not critical but is preferably about 1000 Angstroms. Over the TEOS layer 43, a nitride layer 45 is deposited to a thickness of about 80 Angstroms. Lastly two resist pillars 47 and 49 are formed from a photoresist layer. The resist pillars have lateral dimensions corresponding to desired locations and dimensions of two portions of a single floating gate of a non-volatile floating gate transistor. The resist pillars 47 and 49 will be used to form floating gate masks, or preferably a single floating gate mask with two branches, in the TEOS layer 43. A poly gate for a select transistor, not shown, may also be simultaneously fabricated. Such two transistor memory cells are used in NOR memory arrays and elsewhere.

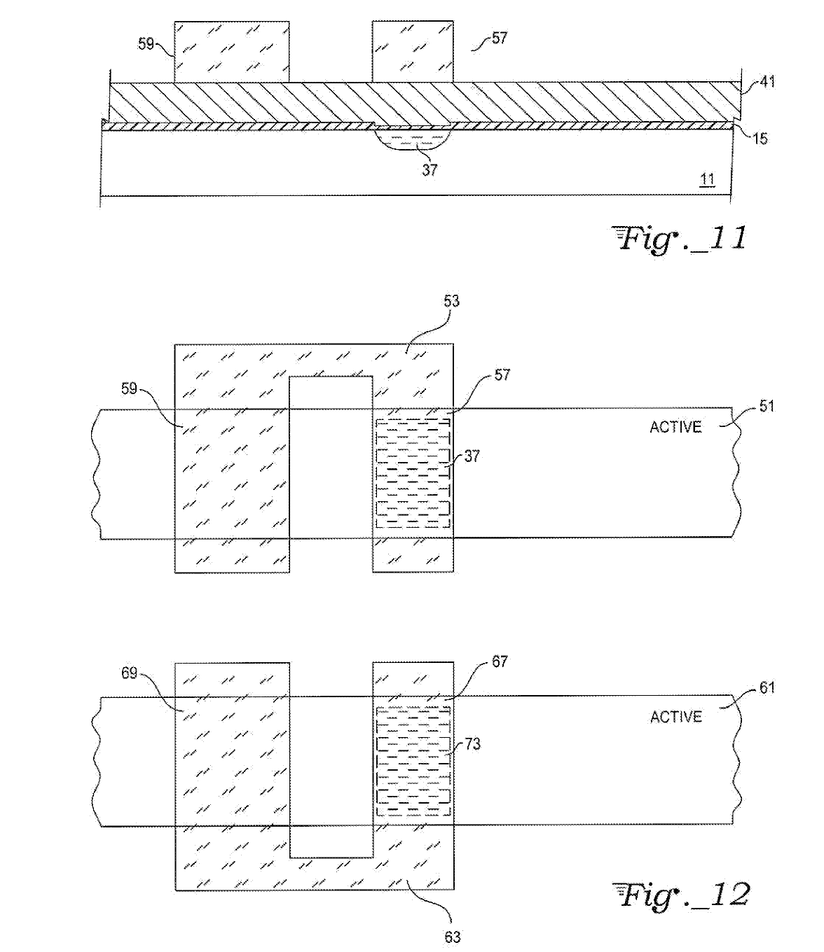

With reference to FIG. 11, the TEOS layer is dry etched to leave a TEOS gate mask with TEOS members 57 and 59. TEOS member 57 is directly over charge region 37 and has a dimension that is at least feature size since it is made by photolithography. TEOS member 59 has a slightly wider dimension.

In the top view of FIG. 12, the TEOS members 57 and 59 are seen to be arms of a unitary TEOS hard mask 53. This hard mask is U-shaped but could be H-shaped or have another shape that will yield a single poly floating gate. The TEOS member arms span an active region stripe 51 defined in the substrate. The active region is typically defined by field oxide barriers, not shown. A second TEOS gate mask 63 of adjacent cell is symmetrically opposite, spanning the active region stripe 61, parallel to active region stripe 51. These two masks define floating poly gates of memory cells, one associated with gate mask 53 and one associated with gate mask 63. In gate mask 53 the implant region 37 of FIG. 11 is shown in the center of the width of the active region stripe 51. A corresponding implant region 73 is associated with gate mask 63. Not shown in FIG. 12 is poly layer 41 and oxide layer 15 of FIG. 11.

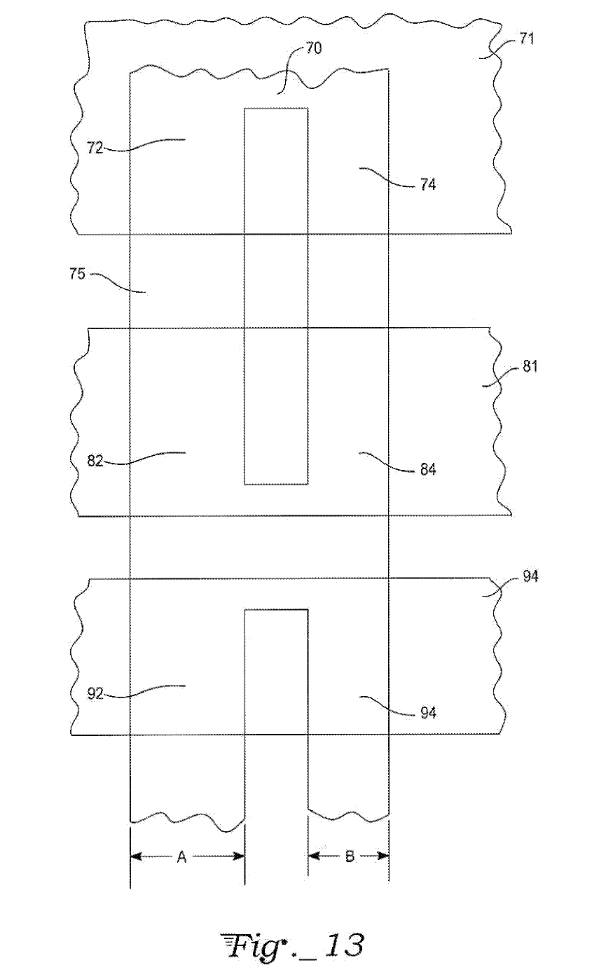

With reference to FIG. 13, active area stripes 71, 81, and 91 are all parallel and would be part of patterning a wafer for a memory array, or the like. All of the stripes defining active areas could be part of a first mask set. Similarly, TEOS masks could be integrated into a single mask 70, to be used for making floating gates, with arm regions 72 and 74 of the mask portion over active area strips 71 joined with arm regions 82 and 84 of the mask portion over active area stripe 81. In turn, arm regions 82 and 84 are joined to arm regions 92 and 94 for making a unitary TEOS stripe mask associated with a plurality of memory cells. One such stripe mask would be associated with each column of the array, while one active area stripe would be associated with each row. In other words a first mask would have TEOS stripe masks for all columns of a memory array and a second mask would define all active areas for all rows of the array. Note that arm regions 72, 82, 92 have dimensions A, while arm regions 74, 84 and 94 have dimension B where A is at least 20% greater than B as a preferred ratio.

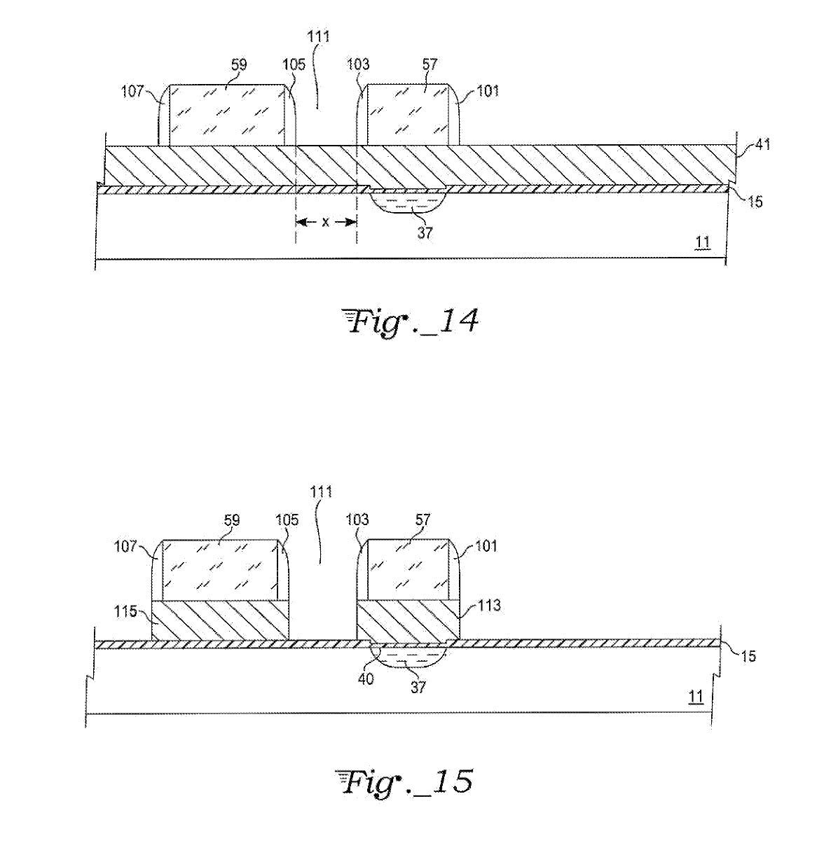

With reference to FIG. 14, the TEOS mask member 57 and 59 over poly layer 41 are widened with spacers 101 and 103 for mask member 57 and spacers 105 and 107 for mask member 59 in order to create a less than feature size opening “x” in region 111. In other words, the widening of the mask members 57 and 59 with spacers creates a narrow aperture 111 between the spacers. By narrow aperture is meant that the aperture is preferably, although not necessarily, smaller than the feature size. In FIG. 15, the aperture is made deeper since all poly is etched to oxide layer 15, except under the masks, leaving a pair of floating poly gate members 113 and 115. Poly floating gate member 113 is directly above implanted charge region 37 and thin window 40. The widening of mask members 57 and 59 with spacers 101, 103, 105 and 107 permits self-aligned ion implantation of source-drain regions 123, 125 and 127, seen in FIG. 16. Returning to FIG. 15, floating gate member 113, including associated spacers has first and second sidewalls defined by spacers 101 and 103. Gate member 115 has third and fourth sidewalls defined by spacers 105 and 107, respectively. Separation distances are optimized for channel lengths as well as other dimensional and performance criteria. Returning to FIG. 16, regions 125 and 127 are joined to implant region 37 by annealing to form a single elongate drain electrode beneath floating gate member 113. The effect of annealing is indicated by dashed line 126 where drain regions 125, 37 and 127 are joined. The source-drain regions 123, 125 and 127 are self-aligned to poly floating gate members 115 and 113. As was seem in FIG. 15, sidewall spacer 101 guides drain implant region 127. Sidewall spacers 103 and 105 guide drain implant region 125, a drain extension. Thermal annealing joins implant region 37 to the implant regions 127 and 125, indicated by dashed line 126, to form a single drain electrode that has been built from three self-aligned implant regions in the two implant steps shown in FIGS. 7 and 16. Sidewall spacer 107 of FIG. 15 guides source implant region 123 for forming a single source electrode region 123 spaced from the drain extension defining a channel. In this manner, the entire source and drain region structures are formed by self-alignment, including a region directly below the tunnel window and on both sides of the tunnel window. After the ion implantation of source-drain regions, the hard mask members 57 and 59 of FIG. 15, with spacers, are removed by both dry and wet etching, leaving the floating poly gate members 113 and 115. The floating poly gate members 113 and 115 are connected, as seen in the top view of FIG. 12, to form the memory transistor having a channel “B”, seen in FIG. 16, between two source-drain regions, region 123 considered as a source and region 125 considered as a drain. In FIG. 17 drain 125 has drain extensions 127 and 37. An ONO film 119 is deposited over the entire structure followed by a control poly layer 129 deposition. Simultaneously with the formation of control poly layer a select gate for a select transistor is formed. The select gate and control gate of the memory transistor are formed in a conventional manner. The select transistor 141 is not shown in FIG. 17 but would be used in a NOR memory array with a non-volatile memory transistor.

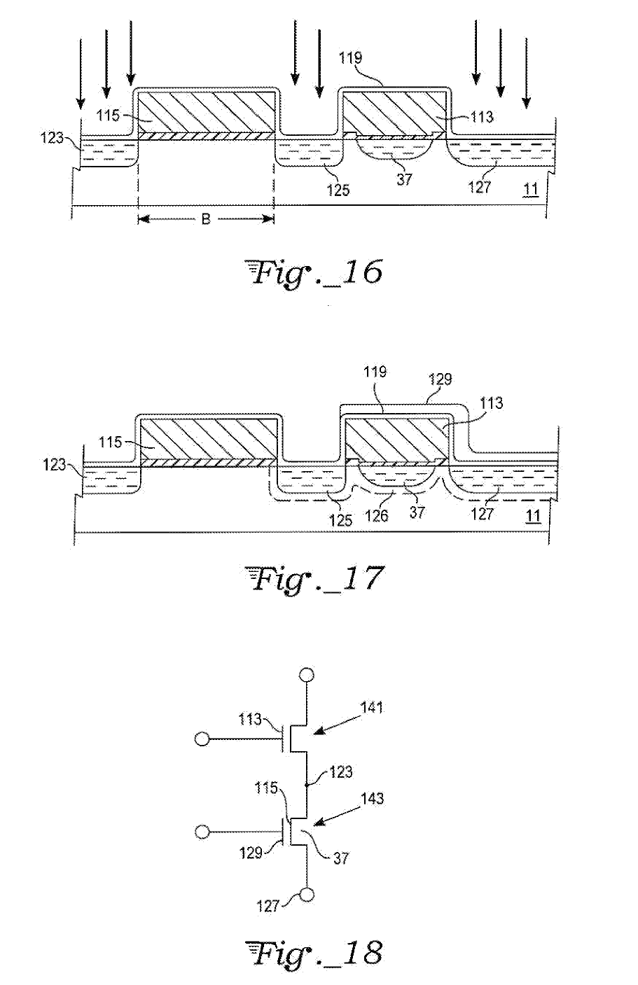

With reference to FIG. 18, a cell having two transistors, namely select transistor 141 and non-volatile memory transistor 143 are shown.

1. Method of making an EEPROM transistor comprising:
on a semiconductor substrate building a spacer mask defining a first aperture;
implanting a charge region in the substrate through the first aperture;
removing the spacer mask;
building a floating gate with first gate member having first and second side walls, the gate member situated over the charge region and a second gate member spaced from the first gate member but electrically joined thereto, the second gate member having third and fourth sidewalls;
using said side walls for self-aligned placement of one source region and two drain regions all adjacent to the side walls, the two drain regions joined to the charge region in the substrate thereby forming a single drain; and
building a control gate over floating gate.

2. The method of claim 1 further defined by situating the first and second gate members such that the second sidewall of the first gate member and the third sidewall of the second gate member define a second aperture for self-aligned placement of a first of the two drain regions.

3. The method of claim 2 further defined by using the fourth sidewall of the second gate member for self-aligned placement of the source region.

4. The method of claim 2 further defined by using the first sidewall of the first gate member for self-aligned placement of a second of the two drain regions.

5. The method of claim 1 further defined by forming the spacer mask by widening a photolithographic mask wherein said first aperture is less than feature size.

6. The method of claim 1 further defined by establishing active region stripes across a semiconductor substrate and building the spacer mask in a stripe.

7. The method of claim 6 further defined by building a single gate mask for the floating gate members.

8. The method of claim 7 further defined by shaping the gate mask as a stripe.

9. The method of claim 7 further defined by orienting the gate mask stripe perpendicular to the active region stripes.

10. The method of claim 2 wherein the second aperture is less than feature size.

11. Method of making an EEPROM transistor comprising:
implanting a first charge region in a semiconductor substrate;
building a tunnel window in an insulative layer over the first charge region;
building a conductive floating gate over the tunnel window with a wall configuration defining three spaced apart self-alignment implant regions in the substrate;
performing self-aligned implantations using the floating gate wall configuration to define second, third and fourth charge regions in the three spaced apart implant regions;
joining first, second and third charge regions as a drain electrode;
establishing the fourth charge region as a source electrode; and
forming a control electrode.

12. The method of claim 11 wherein said joining of charge regions is by thermal annealing.

13. Method of making a non-volatile transistor cell comprising:
on a semiconductor substrate building a spacer mask defining a first aperture;
implanting a charge region in the substrate through the aperture;
building a tunnel window in a layer over the charge window;
depositing a poly layer over the window layer;
building a first and second spaced apart mask members at desired gate locations over the poly layer as a cell mask, the first cell mask member being over the charge region, the cell mask leaving protected and unprotected poly regions;
widening the cell mask members with spacers to establish a second aperture between mask members;
removing unprotected poly regions, leaving first and second spaced apart but electrically joined poly floating gate members, the first poly gate member being over the charge region;
using the cell mask for self-aligned implanting of source-drain regions, the source-drain regions flanking the poly gates;
removing the cell mask with spacers; and
building a control gate at least over the first poly floating gate member.

14. The method of claim 13 further defined by making the first aperture in the spacer mask less than feature size.

15. The method of claim 13 further defined by making the second aperture in the spacer mask less than feature size.

16. The method of claim 13 further defined by simultaneously implanting three source-drain regions.

17. The method of claim 13 further defined by establishing active area stripes on the substrate and building the spacer mask in an active area stripe.

18. The method of claim 17 further defined by building the cell mask in a cell mask stripe perpendicular to an active area stripe.

19. The method of claim 18 further defined by joining a plurality of cell masks in the cell mask stripe.

20. The method of claim 19 further defined by a plurality of cell mask stripes being mutually spaced apart and perpendicular to active area stripes.
